(19) United States
(12) Patent Application Publication
(10) Pub. No.: US 2005/0253159 A1
(43) Pub. Date: Nov. 17, 2005

(54) Semiconductor (LED) chip attachment

(76) Inventors: Steven B. Creswick, Ravenna, MI (US); Jeremy A. Walser, Grand Rapids, MI (US)

Correspondence Address: PRICE, HENEVELD, COOPER, DEWITT, & LITTON,;LLP/GENTEX CORPORATION, 695 KENMOOR, S.E., P O BOX 2567, GRAND RAPIDS, MI, 49501, US

(21) Appl. No.: 10/833,959

(22) Filed: Apr. 28, 2004

(51) Int. Cl. H01L 29/22

(52) U.S. Cl. 257/98

(57) ABSTRACT

A device comprising a semiconductor component having a lower face and a support member having a surface supporting the lower face of the semiconductor component. Attaching material connects the lower face of the semiconductor optical radiation emitting component to the surface of the support member. The surface can include scoring below the lower face of the semiconductor component. Additionally, or as alternative to the scoring, the surface can have a contour for allowing a locating machine to accurately visually locate a placement location for the semiconductor component, for maintaining a position and orientation of each semiconductor component at the placement location on the surface and/or for routing a fluxing agent to a position surrounding the semiconductor component during attachment of the semiconductor component to the support member.

### BACKGROUND

The present invention concerns semiconductor devices, and more particularly relates to attachments for semiconductor components or LED chips.

Semiconductor optical emitting devices, particularly those including inorganic light emitting diodes (LEDs), have become commonplace in a wide variety of consumer and industrial opto-electronic applications. Other types of semiconductor optical emitter devices, such as those including organic light emitting diodes (OLEDs), light emitting polymers (LEPs), and the like, may also be packaged in discrete components suitable as substitutes for conventional inorganic LEDs in many of these applications.

Visible LEDs of all colors are used alone or in small clusters as status indicators on such products as computer monitors, coffee makers, stereo receivers, CD players, VCRs, and the like. Such indicators are also found in a variety of systems such as instrument panels in aircraft, trains, ships, cars, trucks, minivans and sport utility vehicles, etc. Addressable arrays containing hundreds or thousands of visible LEDs are found in moving-message displays such as those found in many airports and stock market trading centers and also as high brightness large-area outdoor television screens found in many sports complexes and on some urban billboards.

Amber, red, and red-orange emitting visible LEDs are used in arrays of up to one hundred devices in visual signaling systems such as vehicle center high mounted stop lamps (CHMSLs), brake lamps, exterior turn signals and hazard flashers, exterior signaling mirrors, and for roadway construction hazard markers. Amber, red, and blue-green emitting visible LEDs are increasingly being used in much larger arrays of up to three hundred devices as stop/slow/go lights at intersections in urban and suburban intersections.

Multi-color combinations of pluralities of visible colored LEDs are being used as the source of projected white light for illumination in binary-complementary and ternary (red-green-blue) RGB illuminators. Such illuminators are useful as vehicle or aircraft maplights, for example, or as vehicle or aircraft reading or courtesy lights, cargo lights, license plate illuminators, backup lights, and exterior mirror puddle lights. Other pertinent uses include portable flashlights and other illuminator applications where rugged, compact, lightweight, high efficiency, long-life, low voltage sources of white illumination are needed. Phosphor-enhanced “white” LEDs may also be used in some of these instances as illuminators.

Infrared (IR) emitting LEDs are being used for remote control and communication in such devices as VCR, TV, CD, and other audio-visual remote control units. Similarly, high intensity IR emitting LEDs are being used for communication between IRDA devices such as desktop, laptop and palmtop computers; personal digital assistants (PDAs); and computer peripherals such as printers, network adapters, pointing devices (“mice,” trackballs, etc.), keyboards, and other computers. IR emitting LEDs and IR receivers also serve as sensors for proximity or presence in industrial control systems, for location or orientation within such opto-electronic devices such as pointing devices and optical encoders, and as read heads in such systems as barcode scanners. IR LED emitters may also be used in a night vision system for automobiles.

Blue, violet, and UV emitting LEDs and LED lasers are being used extensively for data storage and retrieval applications such as reading and writing to high-density optical storage disks.

Performance and reliability of LED components are heavily influenced by the thermal performance of those components and by ambient temperature. Elevated operating temperatures simultaneously reduce the emission efficiency of LEDs and increase the probability of failure in most conditions. This elevated temperature may be the result of high system thermal resistance acting in concert with internal LED power dissipation or may also be the result of high ambient operating temperature or other influence. Regardless of the cause, LED efficiency and reliability are normally adversely affected by increases in temperature. Thus, it is advantageous to minimize temperature rise of LED components attributable to internal power dissipation during operation. This can be accomplished by reducing the conductive, convective, and radiative thermal resistance between the LED component and ambient environment, such as by optimizing the materials and construction of the packaged device containing the LED component. These methods, as applicable to mass-solderable, auto-insertable, and other discrete LED components, are disclosed in commonly assigned U.S. patent application Ser. No. 09/426,795, entitled “SEMICONDUCTOR RADIATION EMITTER PACKAGE,” filed on Oct. 22, 1999, by John K. Roberts et al., now U.S. Pat. No. 6,335,548, and published PCT Application Publication No. PCT/US00/07269, the entire disclosures of which are hereby incorporated by reference.

For high power LED devices and high power density LED devices, system thermal performance is especially critical. LED illuminators and high power signal lights generating more than ten lumens (or more than one watt of power dissipation) are examples of systems which can benefit from improved thermal performance, especially if package area/volume must be minimized (increasing power density).

To limit the operational temperature of the LED, the power that is allowed to be dissipated through the LED is typically limited. To limit the dissipated power, however, the current that may be passed through the LED must be limited, which in turn limits the emitted optical flux of the LED since the emitted optical flux is typically proportional to the electrical current passed through the LED.

Other fundamental properties of LEDs place further restrictions on the useful operational temperature change. Semiconductor LED components, including IR, visible, and UV emitting components, emit light via the physical mechanism of electro-luminescence. Their emission is characteristic of the band gap of the materials from which they are composed and their quantum efficiency varies inversely with their internal temperature. An increase in LED component temperature results in a corresponding decrease in their emission efficiency. This effect is quite significant for all common types of LEDs for visible, UV, and IR emission. Commonly, a 1° C. increase in component temperature typically results in up to a 1 percent reduction in useful radiation and up to a 0.1 nm shift in the peak wavelength of the emission, assuming operation at a constant power. Thus, a temperature change of 40° C. will typically result in a 40 percent reduction in emitted flux and a 4 nm shift in peak wavelength.

From the preceding discussion, it can be seen that to avoid thermal damage and achieve optimal LED emission performance, it is very important to minimize the temperature change experienced by the LED component and package during operation. This may be achieved by limiting power or reducing thermal resistance.

The other forms of radiation emitters mentioned above also experience performance degradation, damage, increased failure probability or accelerated decay if exposed to excessive operating temperatures.

Similar heat dissipation problems exist with respect to other electronic components. For example, large heat sinks are often attached to microprocessors of the type used in personal computers.

Accordingly, an improved heat dissipation package for such electronic components is desirable.

Furthermore, billions of LED components are used in applications such as those cited hereinabove, in part because relatively few standardized LED configurations prevail and due to the fact that these configurations are readily processed by the automated processing equipment used almost universally by the world's electronic assembly industries. Automated processing via mainstream equipment and procedures contributes to low capital cost, low defect rates, low labor cost, high throughput, high precision, high repeatability and flexible manufacturing practices. Without these attributes, the use of LEDs becomes cost prohibitive or otherwise unattractive from a quality standpoint for most high-volume applications.

Two of the most important steps in modern electronic assembly processes are high-speed automated insertion and mass automated soldering. Compatibility with automatic insertion or placement machines and one or more common mass soldering process are critical to large-scale commercial viability of discrete semiconductor optical emitting devices (including LEDs).

Accordingly, improvements in the assembly of semiconductor optical emitting devices is desired.

### SUMMARY OF THE PRESENT INVENTION

An aspect of the present invention is to provide a device comprising a semiconductor component having a lower face and a support member having a surface supporting the lower face of the semiconductor component. Attaching material connects the lower face of the semiconductor component to the surface of the support member. The surface includes at least two non-parallel lines of scoring below the lower face of the semiconductor component.

Another aspect of the present invention is to provide a device comprising a semiconductor optical radiation emitting component having a lower face and a lead frame having a surface supporting the lower face of the semiconductor optical radiation emitting component. Attaching material connects the lower face of the semiconductor optical radiation emitting component to the surface of the support member. The surface includes scoring below the lower face of the semiconductor optical radiation emitting component.

Yet another aspect of the present invention is to provide a device comprising a semiconductor component having a lower face and a support member including a surface supporting the lower face of the semiconductor component. Attaching material connects the lower face of the semiconductor component to the surface of the support member. The support member has a reflective wall surrounding the surface. The surface includes scoring below the lower face of the semiconductor component.

A further aspect of the present invention is to provide a device comprising at least one semiconductor component having a lower face and a support member having a surface supporting the lower face of the at least one semiconductor component. The support member includes a substantially planar area under the lower face of the at least one semiconductor component. Attaching material connects the lower face of the at least one semiconductor component to the planar area of the surface of the support member. The surface has a contour allowing a locating machine to accurately visually locate a placement location for each at least one semiconductor component.

Another aspect of the present invention is to provide a device comprising at least one semiconductor component having a lower face and a support member having a surface supporting the lower face of the at least one semiconductor component. The support member includes a substantially planar area under the lower face of the at least one semiconductor component. Attaching material connects the lower face of the at least one semiconductor component to the planar area of the surface of the support member. The surface has a contour maintaining a position and orientation of each at least one semiconductor component at a placement location on the surface.

Yet another aspect of the present invention is to provide a device comprising at least one semiconductor component having a lower face and a support member having a surface supporting the lower face of the at least one semiconductor component. The support member includes a substantially planar area under the lower face of the at least one semiconductor component. Attaching material connects the lower face of the at least one semiconductor component to the planar area of the surface of the support member. The surface has a contour for routing a fluxing agent to a position surrounding the at least one semiconductor component during attachment of the at least one semiconductor component to the support member.

A further aspect of the present invention is to provide a method of positioning at least one semiconductor component on a surface comprising providing the surface with a contour defining at least one placement location and viewing the contour of the surface with a locating machine to determine the at least one placement location on the surface. The method also includes placing attaching material on the at least one placement location and placing each at least one semiconductor component on one at least one placement location.

Another aspect of the present invention is to provide a method of positioning at least one semiconductor component on a surface comprising providing the surface with a contour defining at least one placement location. The method also includes placing attaching material on the at least one placement location and placing each at least one semiconductor component on the placement location. The method further includes maintaining the at least one semiconductor component on the at least one placement location and in a selected orientation with the contour of the surface.

Yet another aspect of the present invention is to provide a method of routing a fluxing agent during attachment of a semiconductor component on a surface comprising providing a surface having a contour and a planar area. The method also includes placing attaching material on the planar area and placing the semiconductor component on the planar area. The method further includes heating the attaching material and the fluxing agent and routing the fluxing agent to a position surrounding the semiconductor component via the contour of the surface.

These and other aspects, objects, and features of the present invention will be understood and appreciated by those skilled in the art upon studying the following specification, claims, and appended drawings.

### BRIEF DESCRIPTION OF DRAWINGS

FIG. 1A is a perspective view of a device of the present invention.

FIG. 1B is a perspective view of a second embodiment of the device of the present invention.

FIG. 2 is an enlarged perspective exploded view of a surface and semiconductor component of the present invention.

FIG. 3 is an enlarged side view of the surface and semiconductor component of the present invention.

FIG. 4 is an enlarged side view of the surface and semiconductor component of a second embodiment of the present invention.

FIG. 5 discloses a block diagram illustrating a first methodology for positioning the semiconductor component on a surface of the present invention.

FIG. 6 discloses a block diagram illustrating a second methodology for positioning the semiconductor component on a surface of the present invention.

FIG. 7 discloses a block diagram illustrating a methodology for routing a fluxing agent during attachment of the semiconductor component on the surface of the present invention.

FIG. 8 is an enlarged side view of the surface and semiconductor component of a third embodiment of the present invention.

FIG. 9 is an enlarged side view of the surface and semiconductor component of a fourth embodiment of the present invention.

### DETAILED DESCRIPTION OF PREFERRED EMBODIMENTS

Reference will now be made in detail to the present preferred embodiments of the invention, examples of which are illustrated in the accompanying drawings. Wherever possible, the same reference numerals will be used throughout the drawings to refer to the same or like parts.

For purposes of description herein, the terms “upper,” “lower,” “right,” “left,” “rear,” “front,” “vertical,” “horizontal,” “top,” “bottom,” and derivatives thereof shall relate to the invention as viewed by a person looking directly at the radiation emitting device along the principal optical axis of the source. However, it is to be understood that the invention may assume various alternative orientations, except where expressly specified to the contrary. It is also to be understood that the specific device illustrated in the attached drawings and described in the following specification is simply an exemplary embodiment of the inventive concepts defined in the appended claims. Hence, specific dimensions, proportions, and other physical characteristics relating to the embodiment disclosed herein are not to be considered as limiting, unless the claims expressly state otherwise.

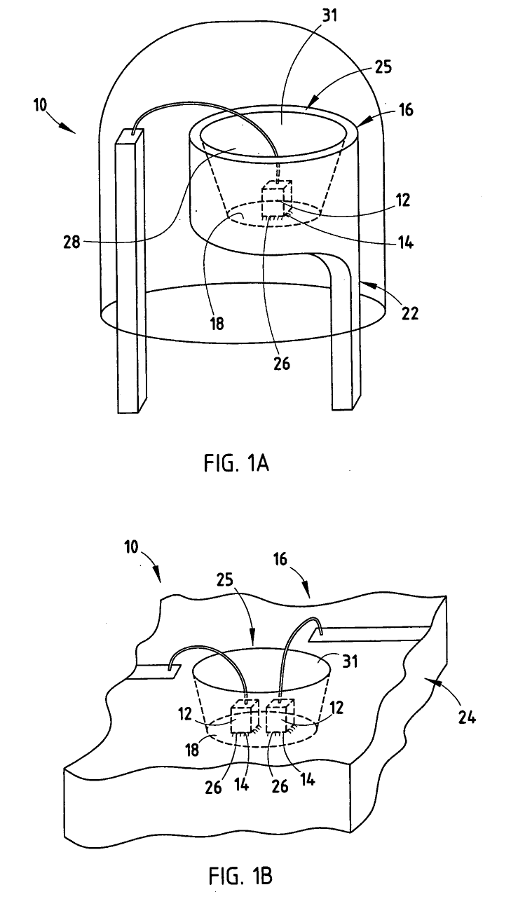

The reference number 10 (FIG. 1) generally designates a first embodiment of a device embodying the present invention. In the illustrated example, the device 10 comprises a semiconductor component 12 having a lower face 14, a support member 16 having a surface 18 supporting the lower face 14 of the semiconductor component 12 and attaching material 20 connecting the lower face 14 of the semiconductor component 12 to the surface 18 of the support member 16. The present invention relates to improvements in the support member 16 to assist in transferring heat from the semiconductor component 12 to the support member 16 and/or attaching the semiconductor component 12 to the support member 16.

In the present invention, the device 10 can include any device having one or more semiconductor components 12. However, several embodiments of the present invention are particularly adapted for radiation emitting devices, and in particular optical radiation emitting devices, useful in both high and low power applications. Such embodiments of the present invention are particularly well suited for use in limited power applications such as vehicles, portable lamps, and specialty lighting. By vehicles, it is meant over-land vehicles, watercraft, aircraft and manned spacecraft, including but not limited to automobiles, trucks, vans, buses, recreational vehicles (RVs), bicycles, motorcycles and mopeds, motorized carts, electric cars, electric carts, electric bicycles, ships, boats, hovercraft, submarines, airplanes, helicopters, space stations, shuttlecraft, and the like. By portable lamps, it is meant camping lanterns, head or helmet-mounted lamps such as for mining, mountaineering, and spelunking, hand-held flashlights, and the like. By specialty lighting it is meant emergency lighting activated during power failures, fires or smoke accumulations in buildings, microscope stage illuminators, billboard front-lighting, backlighting for signs, etc. The optical radiation emitting devices of the present invention may be used as either an illuminator or an indicator. Examples of some of the applications in which the present invention may be utilized are disclosed in commonly assigned U.S. Pat. No. 6,441,943 entitled “INDICATORS AND ILLUMINATORS USING A SEMICONDUCTOR RADIATION EMITTER PACKAGE,” the entire disclosure of which is hereby incorporated herein by reference. The device 10 of the present invention could be used in the following areas in a vehicle: a vanity light in a visor or a headliner; a reading or map light in a headliner, console or a rearview mirror assembly; a dome light; a contour light in a door panel, a rearview mirror assembly, an instrument panel, seats, a headliner, consoles or in pillars of the vehicle; door ground or edge illumination; glove compartment illumination; trunk illumination; turn signals, ground illumination or door handle illumination in a side mirror; tail lights; head lights; roof/side marker lights; instrument panel indicators; display backlights; button backlights; and other places.

Some of the embodiments of the present invention provide a highly reliable, low-voltage, long-lived, light source for vehicles, portable lighting, and specialty lighting capable of producing white light with sufficient luminous intensity to illuminate subjects of interest well enough to be seen and to have sufficient apparent color and contrast so as to be readily identifiable. Several of the radiation emitter devices of the present invention may be well suited for use with AC or DC power sources, pulse-width modulated DC power sources, and electronic control systems. The radiation emitting devices of the present invention may further be used to emit light of various colors and/or to emit non-visible radiation such as IR and UV radiation.

As used herein, the term “radiation emitting device” shall include any structure that generates and emits optical or non-optical radiation, while the term “optical radiation emitting device” includes those radiation emitting devices that emit optical radiation, which includes visible light, near infrared (IR) radiation, and/or ultraviolet (UV) radiation. The optical radiation emitting devices may include electroluminescent sources or other solid-state sources and/or photoluminescent or other sources. Suitable electroluminescent sources include semiconductor optical radiation emitting components. For purposes of the present invention, “semiconductor optical radiation emitting components” comprise any semiconductor material that emits electromagnetic radiation having a wavelength between 100 nm and 2000 nm by the physical mechanism of electroluminescence, upon passage of electrical current through the component or material. The principle function of a semiconductor optical radiation emitting component within the present invention is the conversion of conducted electrical power to radiated optical power. A semiconductor optical radiation component may include a typical IR, visible or UV light emitting diode (LED) chip or die well known in the art and used in a wide variety of prior art devices, or it may include any alternate form of semiconductor optical radiation emitting components as described below.

Alternate forms of semiconductor optical radiation emitting components which may be used in the present invention are light emitting polymers (LEPs), polymer light emitting diodes (PLEDs), organic light emitting diodes (OLEDs), and the like. Such materials and opto-electronic structures made from them are electrically similar to traditional inorganic LEDs, but rely on organic compositions such as derivatives of the conductive polymer polyaniline for electroluminescence. Such semiconductor optical radiation emitting components are relatively new, but may be obtained from sources such as Cambridge Display Technology, Ltd. of Cambridge, and from Uniax of Santa Barbara, Calif.

For brevity, the term semiconductor optical radiation emitting component may be substituted with the term LED or the alternate forms of emitting components described above or known in the art. Examples of semiconductor components suitable for the present invention include varieties of LED chips with associated conductive vias and pads for electrical attachment and that are emissive principally at P—N or N—P junctions within doped inorganic compounds of AlGaAs, AlInGaP, GaAs, GaP, InGaN, AlInGaN, GaN, SiC, ZnSe and the like.

LEDs are a preferred electroluminescent light source for use in the radiation emitting devices of the present invention because LEDs do not suffer appreciable reliability or field-service life degradation when mechanically or electronically switched on and off for millions of cycles. The luminous intensity and illuminance from LEDs closely approximates a linear response function with respect to applied electrical current over a broad range of conditions, making control of their intensity a relatively simple matter. Finally, recent generations of AlInGaP, AlGaAs, InGaN, AlInGaN, and GaN LEDs draw less electrical power per lumen or candela of visible light produced than incandescent lamps, resulting in more cost-effective, compact, and lightweight illuminator wiring harnesses, fuses, connectors, batteries, generators, alternators, switches, electronic controls, and optics. A number of examples have previously been mentioned and are incorporated within the scope of the present invention, although it should be recognized that the present invention has other obvious applications beyond the specific ones mentioned which do not deviate appreciably from the teachings herein and therefore are included in the scope of this invention.

Another preferred radiation source that may be used in the inventive light emitting assembly is a photoluminescent source. Photoluminescent sources produce visible light by partially absorbing visible or invisible radiation and re-emitting visible radiation. Photoluminescent sources are phosphorescent and fluorescent materials, which include fluorescent dyes, pigments, crystals, substrates, coatings, as well as phosphors. Such a fluorescent or phosphorescent material may be excited by an LED or other radiation emitter and may be disposed within or on an LED device, or within or on a separate optical element, such as a lens or diffuser that is not integral with an LED device. Exemplary structures using a fluorescent or phosphorescent source are disclosed in commonly assigned U.S. patent application Ser. No. 09/723,675 entitled “LIGHT EMITTING ASSEMBLY,” filed on Nov. 28, 2000, by Turnbull et al., the entire disclosure of which is hereby incorporated herein by reference.

In the illustrated invention, the attaching material 20 can comprise any material that can attach the semiconductor component 12 to the surface 18 of the support member 16. In one embodiment, the attaching material 20 comprises a generic solder or an adhesive. The solder can comprise non-precious metal alloys or precious metal alloys. For example, the solder comprising non-precious metal alloys can include, in order of major constituent first, a tin-lead combination, a tin-lead-silver combination, a tin-silver combination, a lead-tin combination, a lead-indium combination, a tin-silver-copper combination, indium or an indium-lead combination, and other combinations of these or other elements. Devices 10 of the present invention using the solder comprising non-precious metal alloys as the attaching material 20 can include a high-powered metal oxide silicon field effect transistor (MOSFET), powered rectifiers, a silicon controlled rectifier (SCR), triacs, diacs, power modules, med-high power hybrid modules, ignition modules, transmission modules, brake modules, and Engine Control Unit (ECU) modules or a multitude or other consumer, medical, military and automotive products. The solder comprising precious metal alloys can include, in order of major constituent first, a gold-tin combination, a gold-germanium combination, a gold-silicon combination, and other combinations of these or other elements. Devices 10 of the present invention using the solder comprising precious metal alloys as the attaching material 20 can include the LED, vertical cavity surface emitting lasers (VICSELs) and hermetic fiber-optic devices or a multitude or other consumer, medical, military and automotive products. Adhesives typically primarily comprise a mix of precious, semi-precious and non-precious metal fillers. For example, the adhesives could comprise an organic material with a filler such as silver, palladium-silver, gold, copper, nickel or carbon. Devices 10 of the present invention using the adhesive as the attaching material 20 can include consumer electronic devices, implantable medical devices, hearing aids and wireless telecommunication products or a multitude or other consumer, medical, military and automotive products. The above solders and adhesives are well known to those skilled in the art.

FIGS. 1A and 1B illustrate two embodiments of optical radiation emitting devices 10 of the present invention, with the support member 16 of the device 10 of FIG. 1A comprising a lead frame 22 and the support member 16 and with the support member 16 of the device 10 of FIG. 1B comprising a heat extraction member 24 of a vehicle headlamp. The vehicle headlamp using the heat extraction member 24 of a vehicle headlamp is disclosed in U.S. Pat. No. 6,639,360 entitled “HIGH POWER RADIATION EMITTER DEVICE AND HEAT DISSIPATING PACKAGE FOR ELECTRONIC COMPONENTS,” the entire contents of which are hereby incorporated herein by reference. The semiconductor component 12 of the optical radiation emitting devices 10 of FIG. 1A and FIG. 1B preferably comprises a semiconductor optical radiation emitting component. Optical radiation emitting devices including lead frames 22 and/or printed circuit boards 24 are well-known to those skilled in the art.

In the illustrated example, each of the support members 16 of the devices 10 of FIGS. 1A and 1B include a reflective cup 25 having the surface 18 at a bottom of the reflective cup 25 and a reflective sidewall 28. The semiconductor component 12 is positioned on the surface 18 and therefore is located within the reflective cup 25. The semiconductor optical radiation emitting component 12 located within the reflective cup 25 emits electromagnetic radiation that is propagated out of a top opening 31 of the reflective cup 25 and that is reflected by the reflective sidewall 28 of the reflective cup 25 and out of the top opening 31 of the reflective cup 25. The reflective cup 25 and the emission of electromagnetic radiation out of the reflective cup 25 are well-known to those skilled in the art.

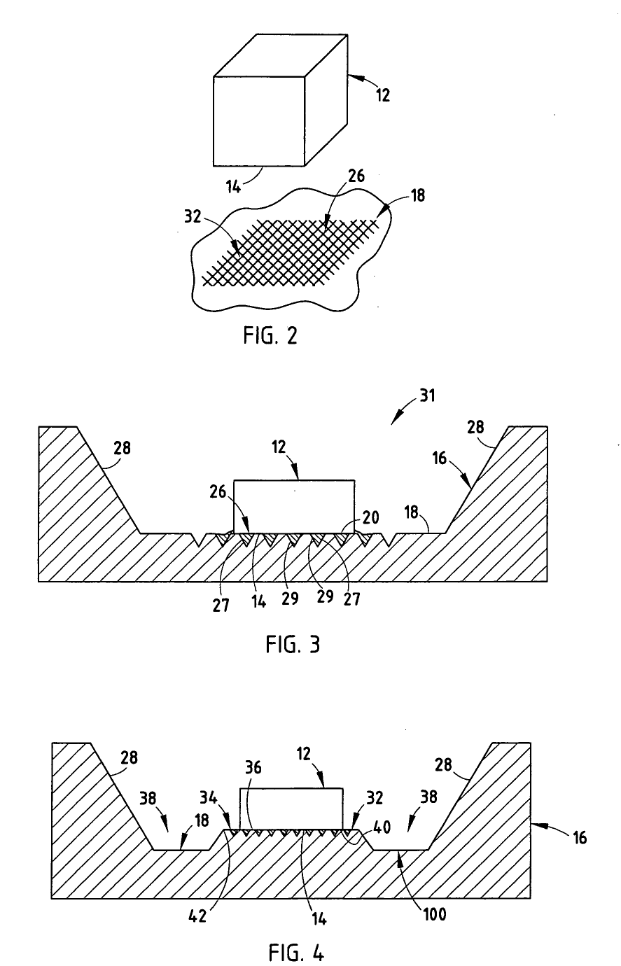

In the illustrated devices 10 of FIGS. 1A and 1B, the surface 18 of the support member 16 of the device 10 includes scoring 26 below the lower face 14 of the semiconductor component 12 to assist in transferring heat from the semiconductor component 12 to the surface 18. The scoring 26 (FIGS. 2-3) comprises a plurality of notches 27 in the scoring 26 adapted to accept the attaching material 20 therein. During assembly of the device 10, the attaching material 20 is positioned on the surface 18 and the semiconductor component 12 is positioned on the attaching material 20. As illustrated in FIG. 2, the scoring 26 covers a larger area than the lower face 14 of the semiconductor component 12. Therefore, as the semiconductor component 12 is moved towards the surface 18, the attaching material 20 will fill the notches 27 of the scoring 26. Preferably, the semiconductor component 12 is moved relatively towards the surface 18 such that the lower face 14 of the semiconductor component 12 abuts the surface 18. As the semiconductor component 12 is moved towards the surface 18, any excess attaching material 20 (i.e., any attaching material 20 in excess of that required to fill the notch 27 below the lower face 14 of the semiconductor component 12) will flow laterally in the notches 27 of the scoring 26 to a position not under the lower face 14 of the semiconductor component 12. Without scoring 26, excess attaching material 20 will climb up side faces 30 of the semiconductor component 12 during assembly of the device 10. This occurs as the semiconductor component 12 is moved relatively towards a non-scored portion of the surface 18. Surface tension wets the attaching material 20 up the side faces 30 of the semiconductor component 12. While the fillet (i.e., attaching material covering the side faces 30 of the semiconductor component 12) formed by the wetting can obstruct some of the radiation being emitted through the side faces 30 of the semiconductor component 12, the fillet is much smaller than that resulting from attachment of the semiconductor component 12 to a surface 16 without scoring. While the devices 10 of FIGS. 1A and 1B are illustrated as being optical radiation emitting devices with the semiconductor component 12 being a semiconductor optical radiation emitting component, it is contemplated that scoring 26 below the lower face 14 of the semiconductor component 12 could apply to any device 10 having any semiconductor component 12.

In the illustrated example, the notches 27 of the scoring comprise a first set of parallel lines and a second set of parallel lines, the first set of parallel lines being non-parallel to the second set of parallel lines. Furthermore, the first set of parallel lines are illustrated as being non-perpendicular to the second set of parallel lines, thereby forming the surface 18 into a plurality of diamond shapes in the area of the scoring 26. However, it is contemplated that the notches 27 of the scoring 26 could be positioned in any configuration. For example, the notches 27 of the scoring 26 could comprise only one set of parallel lines, a first set of parallel lines perpendicular to a second set of parallel lines or any other set or group of sets of straight or curving lines. It is contemplated that the scoring 26 could be stamped, coined, etched, skived, or in any other manner placed into the surface 18 of the support member 16. Furthermore, although the notches 27 of the scoring 26 are illustrated as having a triangular configuration, it is contemplated that the notches 27 could have any geometric configuration.

In the illustrated example, the scoring 26 provides for improved attachment of the semiconductor component 12 to the surface 18, for improved performance of the semiconductor component 12 and for improved heat transfer from the semiconductor component 12 to the surface 18. As illustrated in FIG. 3, one embodiment of the notches 27 of the scoring 26 include a notch surface 29 having attaching material 20 adhered thereto. In the illustrated embodiment, the total area of the notch surface 29 of the notches 27 of the scoring 26 having the attaching material 20 attached thereto is greater that the total area that the attaching material 20 would be attached to if the surface 18 did not have any scoring 26. Therefore, since the scoring 26 in the illustrated embodiment increases the area to which the attaching material 20 is attached, the overall strength of the attachment of the attaching material 20 to the surface 18 of the support member 16 with the scoring 26 is increased over the surface 18 of the support member 16 without the scoring 26.

The illustrated scoring 26 of the surface 18 of the support member 16 also provides for improved performance of the semiconductor component 12. In a typical optical radiation emitting device 10, the semiconductor optical radiation emitting component 12 emits optical radiation out of side faces 30 thereof. Accordingly, the efficiency of the semiconductor optical radiation emitting component 12 can depend on the surface area of the uncovered portion of the side faces 30 of the semiconductor optical radiation emitting component 12. In the present invention, the scoring 26 allows the attaching material 20 to flow into the notches 27 of the scoring 26 as the semiconductor component 12 is moved towards the surface 18 of the support member 16. Without the scoring 26, the attaching material 20 would cover a portion of the side faces 30 of the semiconductor component 12 as the semiconductor component 12 is forced towards the surface 18 of the support member 16. However, since the attaching material 20 can flow into the notches 27 of the scoring 26 of the present invention as the semiconductor component 12 is moved towards the surface 18 of the support member 16, a lesser extent of the side faces 30 of the semiconductor component 12 will be covered, thereby improving the performance of the semiconductor component 12.

In the illustrated example, the scoring 26 of the surface 18 of the support member 16 will also provide for improved heat transfer from the semiconductor component 12 to the surface 18. As illustrated in FIG. 3, the scoring 26 of the surface 18 of the support member 16 allows a portion of the lower face 14 of the semiconductor component 12 to abut against the surface 18 of the support member 16 while at the same time allowing the attachment material 20 to adhere to the lower face 14 of the semiconductor component 12. Typically, the support member 16 has a higher heat transfer coefficient than the attaching material 20. Therefore, any direct contact between the semiconductor component 12 and the support member 16 will increase the heat transfer of the semiconductor component 12 to the support member 16. Accordingly, since the scoring 26 allows a portion of the lower face 14 of the semiconductor component 12 to abut against the surface 18 of the support member 16, the scoring 26 of the surface 18 of the support member 16 will also provide for improved heat transfer from the semiconductor component 12 to the surface 18.

Furthermore, since any excess attaching material 20 can be moved into the scoring 26 not under the lower face 14 of the semiconductor component 12 during assembly of the device 10, tolerances for the amount of attaching material 20 placed onto the surface 18 before placement of the semiconductor component 12 can be relaxed compared to prior art assembly methods as the amount of attaching material 20 will not effect the heat transfer characteristics to the extent that the amount of attaching material 20 effected the heat transfer characteristics of the device made using the prior art assembly methods. Accordingly, the scoring 26 allows the device 10 to be quickly assembled.

In the illustrated invention, the surface 18 of the support member 16 of the device 10 can include a contour 100 that assists in placing the semiconductor component 12 at a placement location 32 on the surface 18. Typically, the device 10 of the present invention requires that the semiconductor device 12 be located at a particular point (i.e., the placement location 32) on the surface 18 of the support member 16. The contour 100 of the surface 18 assists in locating the semiconductor component 12 at the placement location 32 quickly and easily using automatic pattern recognition or visual systems well-known to those skilled in the art.

A first embodiment of the contour 100 is illustrated in FIG. 4, wherein the surface 18 includes a plateau 34 surrounding the placement location 32. The plateau 34 extends upwardly from the surface 18 and includes a top face 36. As illustrated in FIG. 4, a canal 38 is preferably formed in the surface 18 between the plateau 34 and the reflective sidewalls 28 of the reflective cup 25. However, it is contemplated that the plateau 34 could be included on any surface 18 of any support member 16, such that the support member 16 does not require the reflective cup 25, the reflective sidewalls 28 and any resulting canal 38. In one embodiment, the semiconductor component 12 includes a component periphery 40 and the plateau 34 includes a plateau periphery 42 substantially co-extensive with the component periphery 40. Furthermore, in the one embodiment, edges of the plateau periphery 42 are preferably about 0.001-0.002 inches larger than edges of the component periphery 40.

In the illustrated embodiment, the contour 100 of the surface 18 allows a locating machine to accurately visually locate the placement location 32 for the semiconductor component 12. In one embodiment of the present invention, an automated locating machine is used to place the semiconductor component 12 on the placement location 32 during assembly of the device 10. Since the surface 18 of the support member 16 includes the contour 100 comprising the plateau 34 surrounding the placement location 32, the locating machine can easily visually locate the placement location 32. Without the contour 100, the locating machine would not be able to visually locate the placement location 32 and the locating machine would have to be accurately programmed to place the semiconductor component 12 on the surface 18 without inspecting the position of the support member 16. Accordingly, the contour 100 of the surface 18 of the support member 16 allows the locating machine to accurately visually locate the placement location 32 for each semiconductor component 12 on a plurality of support members 18 in an assembly line without ensuring that all support members 16 are identically positioned relative to the locating machine. Therefore, the contour 100 allows the entire assembly process to proceed quickly and accurately without the difficult requirement of having all support members 18 in the assembly line being accurately and substantially identically positioned relative to the locating machine. The locating machine and the method of using the locating machine to visually locate the placement location 32 are well known to those skilled in the art. Commercially available locating machines include those produced by Alphasem AG of Berg/TG, Switzerland under the name Easyline 8032, by ASM Pacific Technology Ltd. of Kwai Chung, Hong Kong, under the name AD900 by ESEC of Cham, Switzerland under the name ESEC 2008HS or by F & K Delvotec Bondtechnik GmbH of Ottobrunn, Germany under the Model No. 4501.

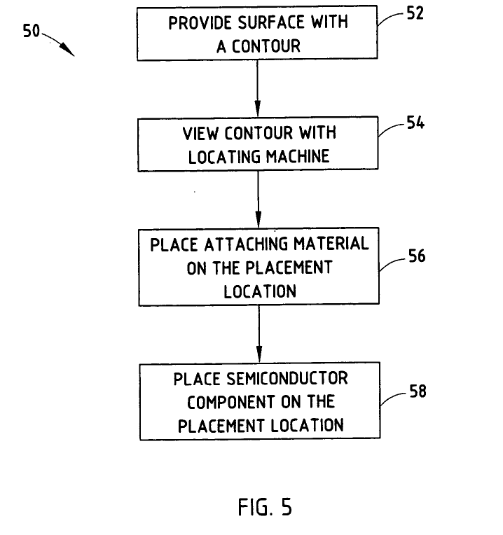

The illustrated contour 100 of the surface 18 of the support member 16 of the present invention provides for accurately positioning the semiconductor component 12 on the surface 18. Referring to FIG. 5, a method 50 of positioning the semiconductor component 12 on the surface 18 is shown. Beginning at step 52 of the method 50 of positioning the semiconductor component 12 on the surface 18, the surface 18 of the support member 16 is provided with the contour 100 defining at least one placement location 32. The contour 100 of the surface 18 is then viewed with the locating machine to determine the placement location 32 on the surface 18 at step 54. Furthermore, the attaching material 20 is placed on the placement location 32 at step 56. It is contemplated that the attaching material 20 can be positioned on the placement location 32 accurately using the above-described locating machine or a separate locating machine to determine the placement location 32 or in any other manner, before or after step 54. After the step 54, the semiconductor component 12 is placed on the placement location 32 at step 58.

In the illustrated embodiment, the contour 100 of the surface 18 of the support member 16 also provides for maintaining a position and orientation of the semiconductor component 12 at the placement location 32 on the surface 18. In the illustrated example, the plateau 34 will maintain the attaching material 20 on the top face 36 thereof because surface tension of the attaching material 20 will maintain the attaching material 20 on the plateau 34 substantially within the plateau periphery 42. Accordingly, when the semiconductor component 12 is placed on the attaching material 20, the surface tension of the attaching material 20 will also maintain the semiconductor component 12 on the plateau 34. Furthermore, since the plateau periphery 42 is co-extensive with the component periphery 40, the attaching material 20 and the semiconductor component 12 will not rotate. Therefore, the contour 100 of the surface 18 of the support member 16 maintains the position and orientation of the semiconductor component 12 at the placement location 32 on the surface 18.

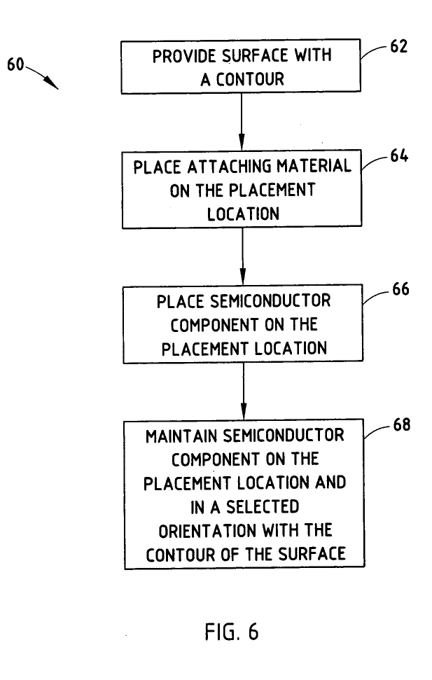

The illustrated contour 100 of the surface 18 of the support member 16 of the present invention provides for maintaining the position and orientation of the semiconductor component 12 at the placement location 32 on the surface 18. Referring to FIG. 6, a method 60 of positioning the semiconductor component 12 on the surface 18 is shown. Beginning at step 62 of the method 60 of positioning the semiconductor component 12 on the surface 18, the surface 18 of the support member 16 is provided with the contour 100 defining at least one placement location 32. Furthermore, the attaching material 20 is placed on the placement location 32 at step 64. After the step 64, the semiconductor component 12 is placed on the placement location 32 at step 66. Therefore, the semiconductor component 12 is maintained on the placement location 32 and in a selected orientation with the contour 100 of the surface 18 at step 68.

In the illustrated embodiment, the contour 100 of the surface 18 of the support member 16 further provides for routing a fluxing agent to a position surrounding the semiconductor component 12 during attachment of the semiconductor component 12 to the support member 16. As is well-known to those skilled in the art, a fluxing agent is often applied as a liquid, paste or gas to the lower face 14 of the semiconductor component 12 and to the surface 18 of the support member 16 prior to attaching the semiconductor component 12 to the surface 18 when the attaching material 20 is a solder. A primary purpose of a fluxing agent is to minimize oxidation of the lower face 14 of the semiconductor component 12 and to the surface 18 of the support member 16 while the device 10 is being heated to a temperature to melt the solder. The fluxing agent covers the lower face 14 of the semiconductor component 12 and to the surface 18 of the support member 16, thereby shielding the lower face 14 and the surface 18 from oxygen and preventing oxidation during heating. Most fluxing agents have a reactive element that is used to remove oxidation already present on the lower face 14 of the semiconductor component 12 and to the surface 18 of the support member 16. Therefore, some fluxing agents in common use are corrosive enough that residue from the fluxing agent are typically cleaned off after soldering. However, the contour 100 of the surface 18 of the support member 16 routes the fluxing agent to a desired position such that the fluxing agent may not have to cleaned off after soldering.

In one embodiment of the present invention, the contour 100 of the surface 18 of the support member 16 routes the fluxing agent to a position surrounding the semiconductor component 12 during attachment of the semiconductor component 12 to the support member 16. As the fluxing agent flows out of a position between the lower face 14 of the semiconductor component 12 and the top face 36 of the plateau 34, the fluxing agent will be routed down the plateau and into the canal 38 formed in the surface 18 between the plateau 34 and the reflective sidewalls 28 of the reflective cup 25. Therefore, the fluxing agent may not have to be cleaned off the surface 18, thereby allowing the assembly speed of the device 10 to increase.

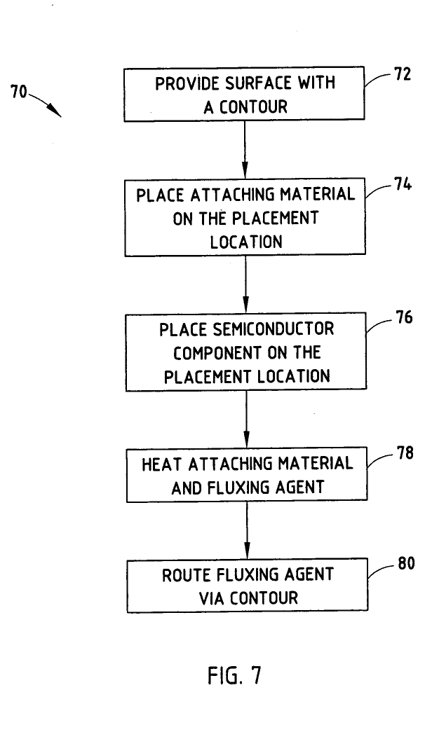

The illustrated contour 100 of the surface 18 of the support member 16 of the present invention provides for routing a fluxing agent to a position surrounding the semiconductor component 12 during attachment of the semiconductor component 12 to the support member 16. Referring to FIG. 7, a method 70 of routing the fluxing agent during attachment of the semiconductor component 12 on the surface 18 is shown. Beginning at step 72 of the method 70 of routing the fluxing agent during attachment of the semiconductor component 12 on the surface 18, the surface 18 of the support member 16 is provided with the contour 100 defining at least one placement location 32. Furthermore, the attaching material 20 is placed on the placement location 32 at step 74. After the step 74, the semiconductor component 12 is placed on the placement location 32 at step 76. Thereafter, the attaching material 20 and the fluxing agent are heated at step 78. Finally, the fluxing agent is routed to a position surrounding the semiconductor component 12 via the contour 100 of the surface 18 at step 80.

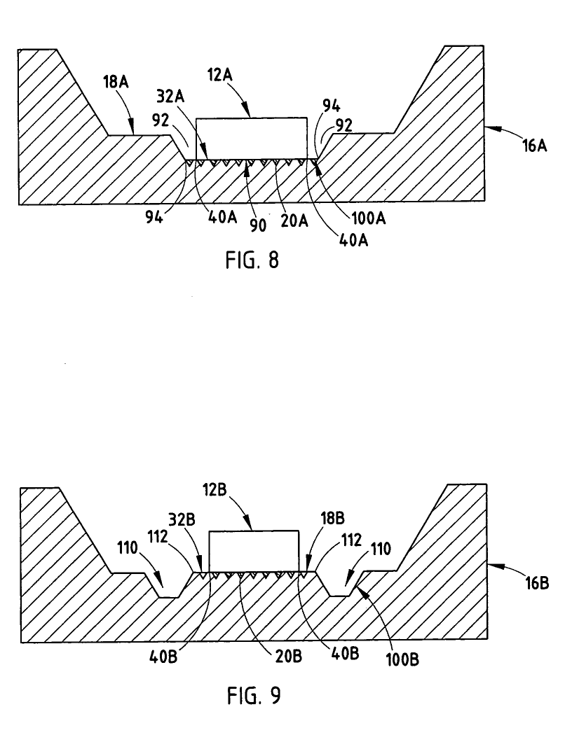

The reference numeral 10a (FIG. 8) generally designates another embodiment of the present invention, having a second embodiment for the contour 100A of the surface 18A. Since the second embodiment for the contour 100A of the surface 18A is similar to the previously described contour 100 of the surface 18, similar parts appearing in FIG. 8 and FIG. 4, respectively, are represented by the same, corresponding reference number, except for the suffix “A” in the numerals of the latter. The second embodiment for the contour 100A of the surface 18A of the support member 16A includes a valley 90 surrounding the placement location 32A. The valley 90 extends downwardly from the surface 18A and includes a top face 36A. As illustrated in FIG. 8, a channel 92 is preferably formed in the surface 18A between the valley 90 and the semiconductor component 12A. In one embodiment, the semiconductor component 12A includes the component periphery 40A and the valley 90 includes a valley periphery 94 substantially co-extensive with the component periphery 40A. Furthermore, in the one embodiment, edges of the valley periphery 94 are preferably about 0.001-0.002 inch larger than edges of the component periphery 40A.

In the illustrated embodiment, the valley 90 of the contour 100A of the surface 18A of the support member 16A of the present invention provides for accurately positioning the semiconductor component 12A on the surface 18A, for maintaining a position and orientation of the semiconductor component 12A at the placement location 32A on the surface 18A and for routing a fluxing agent to a position surrounding the semiconductor component 12A during attachment of the semiconductor component 12A to the support member 16A as in the first embodiment of the present invention. First, the valley 90 allows the locating machine to optically identify the placement location 32A in the same manner that the plateau 34 allows the locating machine to optically identify the placement location 32 in the first embodiment of the present invention. Second, the surface tension of the attaching material 20A in the valley 90 provides for maintaining a position and orientation of the semiconductor component 12A at the placement location 32A on the surface 18A in the same manner that the plateau 34 provides for maintaining the position and orientation of the semiconductor component 12 at the placement location 32 on the surface 18 in the first embodiment of the present invention. Finally, the fluxing agent is routed into the channel 92 in the same manner that the fluxing agent is routed into the canal 38 in the first embodiment of the present invention. However, the channel 92 in the second embodiment of the present invention will be present if the surface 18A is located in any structure, not just a depression (e.g., reflective cup) as in the first embodiment of the present invention.

The reference numeral 10B (FIG. 9) generally designates another embodiment of the present invention, having a third embodiment for the contour 100B of the surface 18B. Since the third embodiment for the contour 100B of the surface 18B is similar to the previously described contour 100 of the surface 18, similar parts appearing in FIG. 9 and FIG. 4, respectively, are represented by the same, corresponding reference number, except for the suffix “B” in the numerals of the latter. The third embodiment for the contour 100B of the surface 18B of the support member 16B includes a channel 110 surrounding the placement location 32B. In one embodiment, the semiconductor component 12B includes the component periphery 40B and the channel 110 includes a channel interior margin 112 substantially co-extensive with the component periphery 40A. Furthermore, in the one embodiment, edges of the channel interior margin 112 are preferably about 0.001-0.002 inch larger than edges of the component periphery 40A.

In the illustrated embodiment, the channel 110 of the contour 100B of the surface 18B of the support member 16B of the present invention provides for accurately positioning the semiconductor component 12A on the surface 18B, for maintaining a position and orientation of the semiconductor component 12B at the placement location 32B on the surface 18B and for routing a fluxing agent to a position surrounding the semiconductor component 12B during attachment of the semiconductor component 12B to the support member 16A as in the first embodiment of the present invention. First, the channel 110 allows the locating machine to optically identify the placement location 32B in the same manner that the plateau 34 allows the locating machine to optically identify the placement location 32 in the first embodiment of the present invention. Second, the surface tension of the attaching material 20B in an area defined within the channel 110 provides for maintaining a position and orientation of the semiconductor component 12B at the placement location 32B on the surface 18B in the same manner that the plateau 34 provides for maintaining the position and orientation of the semiconductor component 12 at the placement location 32 on the surface 18 in the first embodiment of the present invention. Finally, the fluxing agent is routed into the channel 110 in the same manner that the fluxing agent is routed into the canal 38 in the first embodiment of the present invention. However, the channel 110 in the third embodiment of the present invention will be present if the surface 18B is located in any structure, not just a depression (e.g., reflective cup) as in the first embodiment of the present invention.

In the forgoing description, it will be readily appreciated by those skilled in the art that modifications may be made to the invention without departing from the concepts disclosed herein. For example, the placement location 32 can be on the plateau 34, in the valley 90 or defined by the channel 110 and can also include scoring 26 below the lower face 14 of the semiconductor component 12. Furthermore, the contour 100 and the scoring 26 can be used with any device 10 including a support member 16 having a surface 18 and having any semiconductor component 12 thereon. Moreover, the inventive concepts herein can be employed with the support members and the semiconductor devices disclosed in commonly assigned U.S. Pat. No. 6,521,916 entitled “RADIATION EMITTER DEVICE HAVING AN ENCAPSULANT WITH DIFFERENT ZONES OF THERMAL CONDUCTIVITY,” U.S. Pat. No. 6,441,943 entitled “INDICATORS AND ILLUMINATORS USING A SEMICONDUCTOR RADIATION EMITTER PACKAGE,” U.S. Pat. No. 6,639,360 entitled “HIGH POWER RADIATION EMITTER DEVICE AND HEAT DISSIPATING PACKAGE FOR ELECTRONIC COMPONENTS,” U.S. Pat. No. 6,335,548 entitled “SEMICONDUCTOR RADIATION EMITTER PACKAGE,” U.S. Pat. No. 5,803,579 entitled “ILLUMINATOR ASSEMBLY INCORPORATING LIGHT EMITTING DIODES,” U.S. Patent Application Publication No. U.S. 2003/0043590 A1 entitled “VEHICLE LAMP ASSEMBLY WITH HEAT SINK,” U.S. patent application Ser. No. 10/674,830 entitled “RADIATION EMITTER DEVICE HAVING AN INTEGRAL MICRO-GROOVE LENS,” and U.S. patent application Ser. No. 09/723,675 entitled “LIGHT EMITTING ASSEMBLY,” the entire contents of which of all the above are hereby incorporated herein by reference. Such modifications are to be considered as included in the following claims, unless these claims by their language expressly state otherwise.

1. A device comprising:
a semiconductor component having a lower face;
a support member having a surface supporting the lower face of the semiconductor component; and
attaching material connecting the lower face of the semiconductor component to the surface of the support member;
wherein the surface includes at least two non-parallel lines of scoring below the lower face of the semiconductor component.

2. The device of claim 1, wherein:
the semiconductor component comprises a semiconductor chip.

3. The device of claim 2, wherein:
the semiconductor chip emits optical radiation.

4. The device of claim 1, wherein:
the attaching material comprises a solder.

5. The device of claim 1, wherein:
a portion of the lower face of the semiconductor component abuts the surface.

6. The device of claim 1, wherein:
the at least two non-parallel lines of scoring comprises a first set of parallel lines and a second set of parallel lines, the first set of parallel lines being non-parallel to the second set of parallel lines.

7. The device of claim 6, wherein:
the first set of parallel lines are non-perpendicular to the second set of parallel lines.

8. The device of claim 1, wherein:
the support member comprises a lead frame.

9. The device of claim 1, wherein:
the support member comprises a reflective cup, wherein the surface is located within the reflective cup.

10. A device comprising:
a semiconductor optical radiation emitting component having a lower face;
a lead frame having a surface supporting the lower face of the semiconductor optical radiation emitting component; and
attaching material connecting the lower face of the semiconductor optical radiation emitting component to the surface of the support member;
wherein the surface includes scoring below the lower face of the semiconductor optical radiation emitting component.

11. The device of claim 10, wherein:
the semiconductor optical radiation emitting component comprises a semiconductor chip.

12. The device of claim 10, wherein:
the attaching material comprises a solder.

13. The device of claim 10, wherein:
a portion of the lower face of the semiconductor optical radiation emitting component abuts the surface.

14. The device of claim 10, wherein:
the scoring comprises at least two non-parallel lines of scoring.

15. The device of claim 14, wherein:
the at least two non-parallel lines of scoring comprises a first set of parallel lines and a second set of parallel lines, the first set of parallel lines being non-parallel to the second set of parallel lines.

16. The device of claim 15, wherein:
the first set of parallel lines are non-perpendicular to the second set of parallel lines.

17. The device of claim 10, wherein:
the lead frame comprises a reflective cup, wherein the surface is located within the reflective cup.

18. A device comprising:
a semiconductor component having a lower face;
a support member including a surface supporting the lower face of the semiconductor component; and
attaching material connecting the lower face of the semiconductor component to the surface of the support member;
the support member having a reflective wall surrounding the surface;
wherein the surface includes scoring below the lower face of the semiconductor component.

19. The device of claim 18, wherein:
the semiconductor component comprises a semiconductor chip.

20. The device of claim 19, wherein:
the semiconductor chip emits optical radiation.

21. The device of claim 18, wherein:
the attaching material comprises a solder.

22. The device of claim 18, wherein:
a portion of the lower face of the semiconductor component abuts the surface.

23. The device of claim 18, wherein:
the scoring comprises at least two non-parallel lines of scoring.

24. The device of claim 23, wherein:
the at least two non-parallel lines of scoring comprises a first set of parallel lines and a second set of parallel lines, the first set of parallel lines being non-parallel to the second set of parallel lines.

25. The device of claim 24, wherein:
the first set of parallel lines are non-perpendicular to the second set of parallel lines.

26. The device of claim 19, wherein:
the reflecting wall defines a reflective cup, wherein the surface is located within the reflective cup.

27. A device comprising:
at least one semiconductor component having a lower face;
a support member having a surface supporting the lower face of the at least one semiconductor component, the support member including a substantially planar area under the lower face of the at least one semiconductor component; and
attaching material connecting the lower face of the at least one semiconductor component to the planar area of the surface of the support member;
the surface having a contour allowing a locating machine to accurately visually locate a placement location for each at least one semiconductor component.

28. The device of claim 27, wherein:
the at least one semiconductor component comprises a semiconductor chip.

29. The device of claim 28, wherein:
the semiconductor chip emits optical radiation.

30. The device of claim 27, wherein:
the attaching material comprises a solder.

31. The device of claim 27, wherein:
the contour maintains a position and orientation of each at least one semiconductor component at the placement location on the surface.

32. The device of claim 27, wherein:
the contour is configured to route a fluxing agent during attachment of the at least one semiconductor component to the support member.

33. The device of claim 27, wherein:
the contour comprises a valley surrounding the placement location.

34. The device of claim 33, wherein:
the at least one semiconductor component includes a component periphery; and
the valley includes a valley periphery substantially co-extensive with the component periphery.

35. The device of claim 34, wherein:
edges of the valley periphery are about 0.001-0.002 inch larger than edges of the component periphery.

36. The device of claim 27, wherein:
the contour comprises a channel in the surface surrounding the placement location.

37. The device of claim 36, wherein:
the at least one semiconductor component includes a component periphery; and
the channel includes a channel interior margin substantially co-extensive with the component periphery.

38. The device of claim 27, wherein:
edges of the channel interior margin are about 0.001-0.002 inch larger than edges of the component periphery.

39. The device of claim 27, wherein:
the contour comprises a plateau surrounding the placement location.

40. The device of claim 39, wherein:
the at least one semiconductor component includes a component periphery; and
the plateau includes a plateau periphery substantially co-extensive with the component periphery.

41. The device of claim 40, wherein:
edges of the plateau periphery are about 0.001-0.002 inch larger than edges of the component periphery.

42. The device of claim 27, wherein:
the at least one semiconductor component comprises a plurality of semiconductor components; and
the contour allows the locating machine to accurately visually locate the placement location for each of the plurality of semiconductor components.

43. The device of claim 27, wherein:
wherein the surface includes scoring below the lower face of the semiconductor component.

44. The device of claim 43, wherein:
the scoring comprises at least two non-parallel lines of scoring.

45. The device of claim 44, wherein:
the at least two non-parallel lines of scoring comprises a first set of parallel lines and a second set of parallel lines, the first set of parallel lines being non-parallel to the second set of parallel lines.

46. The device of claim 45, wherein:
the first set of parallel lines are non-perpendicular to the second set of parallel lines.

47. A device comprising:
at least one semiconductor component having a lower face;
a support member having a surface supporting the lower face of the at least one semiconductor component, the support member including a substantially planar area under the lower face of the at least one semiconductor component; and
attaching material connecting the lower face of the at least one semiconductor component to the planar area of the surface of the support member;
the surface having a contour maintaining a position and orientation of each at least one semiconductor component at a placement location on the surface.

48. The device of claim 47, wherein:
the at least one semiconductor component comprises a semiconductor chip.

49. The device of claim 48, wherein:
the semiconductor chip emits optical radiation.

50. The device of claim 47, wherein:
the attaching material comprises a solder.

51. The device of claim 47, wherein:
the contour allows a locating machine to accurately visually locate the placement location for each at least one semiconductor component.

52. The device of claim 47, wherein:
the contour is configured to route a fluxing agent during attachment of the at least one semiconductor component to the support member.

53. The device of claim 47, wherein:
the contour comprises a valley surrounding the placement location.

54. The device of claim 53, wherein:
the at least one semiconductor component includes a component periphery; and
the valley includes a valley periphery substantially co-extensive with the component periphery.

55. The device of claim 54, wherein:
edges of the valley periphery are about 0.001-0.002 inch larger than edges of the component periphery.

56. The device of claim 47, wherein:
the contour comprises a channel in the surface surrounding the placement location.

57. The device of claim 56, wherein:
the at least one semiconductor component includes a component periphery; and
the channel includes a channel interior margin substantially co-extensive with the component periphery.

58. The device of claim 57, wherein:
edges of the channel interior margin are about 0.001-0.002 inch larger than edges of the component periphery.

59. The device of claim 47, wherein:
the contour comprises a plateau surrounding the placement location.

60. The device of claim 59, wherein:
the at least one semiconductor component includes a component periphery; and
the plateau includes a plateau periphery substantially co-extensive with the component periphery.

61. The device of claim 60, wherein:
edges of the plateau periphery are about 0.001-0.002 inch larger than edges of the component periphery.

62. The device of claim 47, wherein:
the at least one semiconductor component comprises a plurality of semiconductor components; and
the contour maintains the position and orientation of each one of the plurality of semiconductor components at the placement location.

63. The device of claim 47, wherein:
wherein the surface includes scoring below the lower face of the semiconductor component.

64. The device of claim 63, wherein:
the scoring comprises at least two non-parallel lines of scoring.

65. The device of claim 64, wherein:
the at least two non-parallel lines of scoring comprises a first set of parallel lines and a second set of parallel lines, the first set of parallel lines being non-parallel to the second set of parallel lines.

66. The device of claim 65, wherein:
the first set of parallel lines are non-perpendicular to the second set of parallel lines.

67. A device comprising:
at least one semiconductor component having a lower face;
a support member having a surface supporting the lower face of the at least one semiconductor component, the support member including a substantially planar area under the lower face of the at least one semiconductor component; and
attaching material connecting the lower face of the at least one semiconductor component to the planar area of the surface of the support member;
the surface having a contour for routing a fluxing agent to a position surrounding the at least one semiconductor component during attachment of the at least one semiconductor component to the support member.

68. The device of claim 67, wherein:
the at least one semiconductor component comprises a semiconductor chip.

69. The device of claim 68, wherein:
the semiconductor chip emits optical radiation.

70. The device of claim 67, wherein:
the attaching material comprises a solder.

71. The device of claim 67, wherein:
the contour maintains a position and orientation of each at least one semiconductor component at a placement location on the surface.

72. The device of claim 67, wherein:
the contour allows a locating machine to accurately visually locate the placement location for each at least one semiconductor component.

73. The device of claim 67, wherein:
the contour comprises a valley surrounding the placement location.

74. The device of claim 73, wherein:
the at least one semiconductor component includes a component periphery; and
the valley includes a valley periphery substantially co-extensive with the component periphery.

75. The device of claim 74, wherein:
edges of the valley periphery are about 0.001-0.002 inch larger than edges of the component periphery.

76. The device of claim 75, wherein:
the contour comprises a channel in the surface surrounding the placement location.

77. The device of claim 76, wherein:
the at least one semiconductor component includes a component periphery; and
the channel includes a channel interior margin substantially co-extensive with the component periphery.

78. The device of claim 77, wherein:
edges of the channel interior margin are about 0.001-0.002 inch larger than edges of the component periphery.

79. The device of claim 67, wherein:
the contour comprises a plateau surrounding the placement location.

80. The device of claim 79, wherein:
the at least one semiconductor component includes a component periphery; and
the plateau includes a plateau periphery substantially co-extensive with the component periphery.

81. The device of claim 80, wherein:
edges of the plateau periphery are about 0.001-0.002 inch larger than edges of the component periphery.

82. The device of claim 67, wherein:
the at least one semiconductor component comprises a plurality of semiconductor components; and
the contour routes the fluxing agent for each of the plurality of semiconductor components during attachment of the plurality of semiconductor components to the support member.

83. The device of claim 67, wherein:
wherein the surface includes scoring below the lower face of the semiconductor component.

84. The device of claim 83, wherein:
the scoring comprises at least two non-parallel lines of scoring.

85. The device of claim 84, wherein:
the at least two non-parallel lines of scoring comprises a first set of parallel lines and a second set of parallel lines, the first set of parallel lines being non-parallel to the second set of parallel lines.

86. The device of claim 85, wherein:
the first set of parallel lines are non-perpendicular to the second set of parallel lines.

87. A method of positioning at least one semiconductor component on a surface comprising:
providing the surface with a contour defining at least one placement location;
viewing the contour of the surface with a locating machine to determine the at least one placement location on the surface;
placing attaching material on the at least one placement location; and
placing each at least one semiconductor component on one at least one placement location.

88. The method of positioning at least one semiconductor component on the surface of claim 87, wherein:
the at least one semiconductor comprises a plurality of semiconductor components;
providing the surface with the contour defining at least one placement location comprises providing the surface with the contour defining a plurality of placement locations;
viewing the contour of the surface with the locating machine to determine the at least one placement location on the surface comprises viewing the contour of the surface with the locating machine to determine each one of the placement locations;
placing attaching material on the at least one placement location comprises placing attaching material on each placement location; and
placing each at least one semiconductor component on one at least one placement location comprises placing each of the plurality of semiconductor components on one of the plurality of placement locations.

89. A method of positioning at least one semiconductor component on a surface comprising:
providing the surface with a contour defining at least one placement location;
placing attaching material on the at least one placement location;
placing each at least one semiconductor component on the placement location; and
maintaining the at least one semiconductor component on the at least one placement location and in a selected orientation with the contour of the surface.

90. The method of positioning at least one semiconductor component on the surface of claim 89, wherein:
the at least one semiconductor comprises a plurality of semiconductor components;
providing the surface with the contour defining at least one placement location comprises providing the surface with the contour defining a plurality of placement locations;
placing attaching material on the at least one placement location comprises placing attaching material on each placement location; and
placing each at least one semiconductor component on one at least one placement location comprises placing each of the plurality of semiconductor components on one of the plurality of placement locations; and
maintaining the at least one semiconductor component on the at least one placement location and in the selected orientation with the contour of the surface comprises maintaining each of the plurality of semiconductor components on one of the plurality of placement locations.

91. A method of routing a fluxing agent during attachment of a semiconductor component on a surface comprising:
providing a surface having a contour and a planar area;
placing attaching material on the planar area;
placing the semiconductor component on the planar area;
heating the attaching material and the fluxing agent; and
routing the fluxing agent to a position surrounding the semiconductor component via the contour of the surface.
